(19) United States
(12) Patent Application Publication
(10) Pub. No.: US 2025/0370021 A1
(43) Pub. Date: Dec. 4, 2025

(54) RYDBERG SENSOR PASSIVE ANTENNA RADIO

(71) Applicant: T-MOBILE INNOVATIONS LLC, Overland Park, KS (US)

(72) Inventor: Chad Chun Fai AU, Kirkland, WA (US)

(21) Appl. No.: 18/732,325

(22) Filed: Jun. 3, 2024

(51) Int. Cl. G01R 29/08; G01S 7/03

(52) U.S. Cl. CPC G01R 29/0878; G01S 7/032

(57) ABSTRACT

Aspects provided herein provide methods and systems for utilizing a Rydberg sensor passive antenna radio system. Initially, receiver portions of a passive antenna are replaced with a Rydberg sensor. Radio frequency (RF) carrier signals are received at the Rydberg sensor. A modulated signal corresponding to the RF carrier signals is provided from the Rydberg sensor to the base station via an optical fiber.

### BACKGROUND

In general, remote radio units (RRUs) operating in wireless networks are deployed to locate the radio frequency (RF) electronics as close to the antenna as possible to minimize cable loss between them. The transmitting and receiving RF paths are commonly duplex and share antenna elements among the various RF branches. The RRU interfaces with base band units. A passive multi-band antenna consists of radiating elements is tuned to operate in various design frequencies. The elements can be arranged in a periodic 1D or 2D arrays and are protected from the outdoor environment by a surrounding dielectric radome. Each array terminates into a RF connector. Each antenna port is connected to each of the RRU RF ports using coaxial jumper cables.

### SUMMARY

A high-level overview of various aspects of the present technology is provided in this section to introduce a selection of concepts that are further described below in the detailed description section of this disclosure. This summary is not intended to identify key or essential features of the claimed subject matter, nor is it intended to be used as an aid in isolation to determine the scope of the claimed subject matter.

According to aspects herein, methods, apparatus, and systems are provided for utilizing a Rydberg sensor in a passive antenna. Initially, receiver portions of a passive antenna are replaced with a Rydberg sensor. RF carrier signals are received at the Rydberg sensor. A modulated signal corresponding to the RF carrier signals is provided from the Rydberg sensor to the base station via an optical fiber.

### BRIEF DESCRIPTION OF THE SEVERAL VIEWS OF THE DRAWINGS

Implementations of the present disclosure are described in detail below with reference to the attached drawing figures, wherein:

FIG. 1 depicts a diagram of an exemplary network environment in which implementations of the present disclosure may be employed, in accordance with aspects herein;

FIG. 2 depicts a diagram of an exemplary Rydberg sensor passive antenna, suitable for use in a network environment, in accordance with aspects herein;

FIG. 3 depicts a diagram of an exemplary passive antenna with a Rydberg sensor, suitable for use in a network environment, in accordance with aspects herein

FIG. 4 is a flow diagram of an exemplary method for utilizing a Rydberg sensor in a passive antenna, in accordance with aspects herein; and

FIG. 5 depicts an exemplary computing device suitable for use in implementations of the present disclosure, in accordance with aspects herein.

### DETAILED DESCRIPTION

The subject matter of embodiments of the invention is described with specificity herein to meet statutory requirements. However, the description itself is not intended to limit the scope of this patent. Rather, the inventors have contemplated that the claimed subject matter might be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

Throughout this disclosure, several acronyms and shorthand notations are employed to aid the understanding of certain concepts pertaining to the associated system and services. These acronyms and shorthand notations are intended to help provide an easy methodology of communicating the ideas expressed herein and are not meant to limit the scope of embodiments described in the present disclosure. The following is a list of these acronyms:
3G Third-Generation Wireless Technology
4G Fourth-Generation Cellular Communication System
5G Fifth-Generation Cellular Communication System
6G Sixth-Generation Cellular Communication System
AI Artificial Intelligence
CD-ROM Compact Disk Read Only Memory
CDMA Code Division Multiple Access
eNodeB Evolved Node B
GIS Geographic/Geographical/Geospatial Information System
gNodeB Next Generation Node B
GPRS General Packet Radio Service
GSM Global System for Mobile communications
iDEN Integrated Digital Enhanced Network
DVD Digital Versatile Discs
EEPROM Electrically Erasable Programmable Read Only Memory
LED Light Emitting Diode
LTE Long Term Evolution
MIMO Multiple Input Multiple Output
MD Mobile Device
ML Machine Learning
PC Personal Computer
PCS Personal Communications Service
PDA Personal Digital Assistant
PDSCH Physical Downlink Shared Channel
PHICH Physical Hybrid ARQ Indicator Channel
PUCCH Physical Uplink Control Channel
PUSCH Physical Uplink Shared Channel
RAM Random Access Memory
RET Remote Electrical Tilt
RF Radio-Frequency
RFI Radio-Frequency Interference
R/N Relay Node
RNR Reverse Noise Rise
ROM Read Only Memory
RRU Remote Radio Unit
RSRP Reference Signal Receive Power
RSRQ Reference Signal Receive Quality
RSSI Received Signal Strength Indicator
SINR Transmission-to-Interference-Plus-Noise Ratio
SNR Transmission-to-noise ratio
SON Self-Organizing Networks
TDMA Time Division Multiple Access
TXRU Transceiver (or Transceiver Unit)
UE User Equipment
UMTS Universal Mobile Telecommunications Systems
WCD Wireless Communication Device (interchangeable with UE)

Further, various technical terms are used throughout this description. An illustrative resource that fleshes out various aspects of these terms can be found in Newton's Telecom Dictionary, 32nd Edition (2022).

By way of background, a traditional telecommunications network employs a plurality of base stations (i.e., access point, node, cell sites, cell towers) to provide network coverage. The base stations are employed to broadcast and transmit transmissions to user devices of the telecommunications network. An access point may be considered to be a portion of a base station that may comprise an antenna, a radio, and/or a controller. In aspects, an access point is defined by its ability to communicate with a user equipment (UE), such as a wireless communication device (WCD), according to a single protocol (e.g., 3G, 4G, LTE, 5G, and the like); however, in other aspects, a single access point may communicate with a UE according to multiple protocols.

A base station may comprise one access point or more than one access point. Factors that can affect the telecommunications transmission include, e.g., location and size of the base stations, and frequency of the transmission, among other factors. The base stations are employed to broadcast and transmit transmissions to user devices of the telecommunications network. Traditionally, the base station establishes uplink (or downlink) transmission with a mobile handset over a single frequency that is exclusive to that particular uplink connection (e.g., an LTE connection with an eNodeB). In this regard, typically only one active uplink connection can occur per frequency. The base station may include one or more sectors served by individual transmitting/receiving components associated with the base station (e.g., antenna arrays controlled by an eNodeB). These transmitting/receiving components together form a multi-sector broadcast arc for communication with mobile handsets linked to the base station.

As used herein, “base station” is one or more transmitters or receivers or a combination of transmitters and receivers, including the accessory equipment, necessary at one location for providing a service involving the transmission, emission, and/or reception of radio waves for one or more specific telecommunication purposes to a mobile station (e.g., a UE), wherein the base station is not intended to be used while in motion in the provision of the service.

The term/abbreviation UE (also referenced herein as a user device or wireless communications device (WCD)) can include any device employed by an end-user to communicate with a telecommunications network, such as a wireless telecommunications network. A UE can include a mobile device, a mobile broadband adapter, or any other communications device employed to communicate with the wireless telecommunications network.

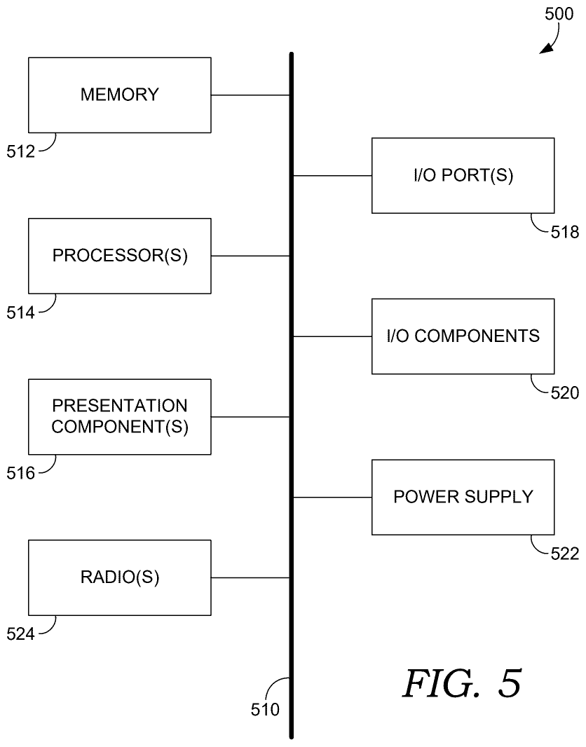

For an illustrative example, a UE can include cell phones, smartphones, tablets, laptops, small cell network devices (such as micro cell, pico cell, femto cell, customer premises equipment (CPE) for fixed wireless access, or similar devices), and so forth. Further, a UE can include a sensor or set of sensors coupled with any other communications device employed to communicate with the wireless telecommunications network; such as, but not limited to, a camera, a weather sensor (such as a rain gage, pressure sensor, thermometer, hygrometer, and so on), a motion detector, or any other sensor or combination of sensors. A UE, as one of ordinary skill in the art may appreciate, generally includes one or more antennas coupled to a radio for exchanging (e.g., transmitting and receiving) transmissions with a nearby base station or access point. A UE may be, in an embodiment, similar to device 500 described herein with respect to FIG. 5.

In conventional cellular communications technology, the remote radio heads with a passive antenna operating in wireless networks, whether terrestrial or non-terrestrial, comprise of the antenna array aperture with radiating elements mated via coaxial RF cables to the RRU containing power amplifiers, signal detectors, low noise amplifiers, RF duplexers/filters, and RF control components. These systems are efficient because the power amplifiers and receiver electronics are placed as close as possible to the antenna aperture, minimizing signal loss in both transmitting and receiving. The transmitting and receiving functions also share the same set of antenna elements through duplex filters.

Nonetheless, despite the efficiency of this architecture, these radio units have a certain finite capability envelope, such that the limit is set by the user equipment (UE) uplink power amplifier and bandwidth capability, meaning that the link budget, and thus maximum coverage radius, is uplink limited. However efficient, the duplex filters do impose a finite amount of signal loss in the receive paths, resulting in a quantifiable penalty to the uplink link budget. While the conductors in the coaxial RF cables connecting the passive antenna to the RRU and the radiating element and the antenna system overall has low resistance, the electrical current induced must overcome this resistance for it to be transmitted to the receiver. Moreover, when the radiating element encounters an electromagnetic field, an electrical current is induced, which is detected by the receiver. However, the presence of the radiating element actually disturbs the field, resulting in some distortion to the signal, Accordingly, a sufficiently strong signal is needed to overcome the uncertainty caused by this disturbance, however small it might be.

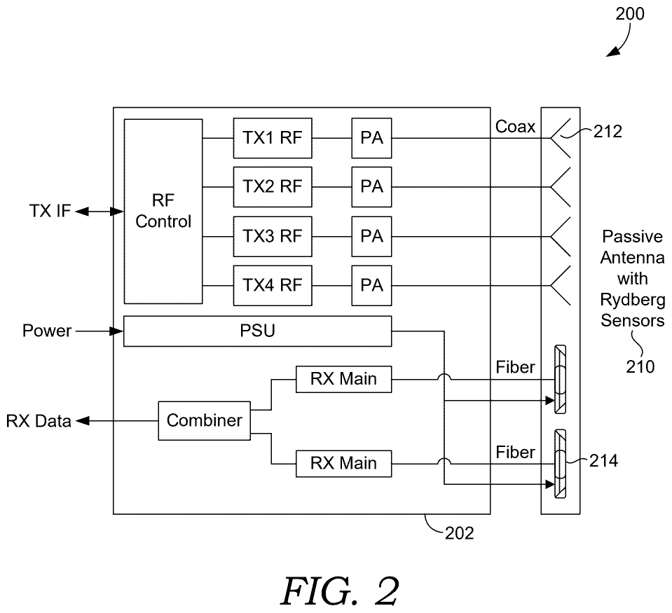

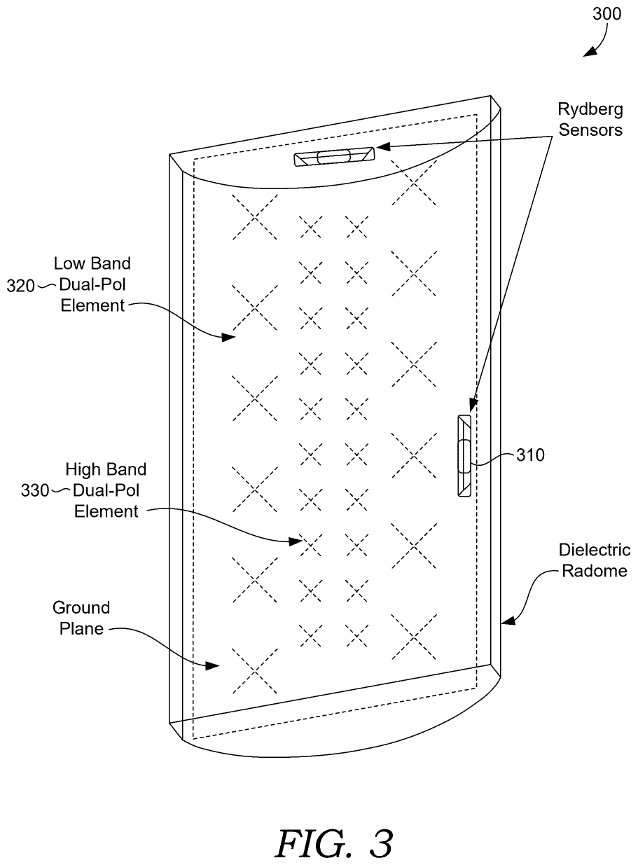

The present disclosure is directed to utilizing a Rydberg sensor in a passive antenna with RRU system. The atoms of a Rydberg atom-based sensor react to a much smaller electric field intensity that than that needed in conventional active antenna systems and overcome the conductor's resistance in exciting the induced current. More simply, the detection of fainter signals is enabled by the Rydberg sensor. Additionally, the glass cell of the Rydberg sensor results in less disturbance in an electromagnetic field than a conventional active antenna system. In other words, there is less distortion to the signal. Overall, uplink performance is greatly improved. While FIGS. 2 and 3 depict two Rydberg sensors, it should be appreciated that multiple sensors may be employed as needed to support multiple frequency bands, polarizations, and MIMO configurations.

Because the Rydberg sensor provides a more efficient electromagnetic field sensing device, the resulting RRU architecture can also simplified. For example, the coaxial cables and duplexers/filters for dedicated transmitting and receiving paths can be removed which lends to reduced losses and a cleaner RF system (i.e., lower noise in uplink). The wavelengths of the lasers in the Rydberg sensor can also be selected to correspond to RF operating frequencies which minimizes the need for additional filtering. Since the Rydberg sensor can extract the in-phase component and a quadrature-phase component (IQ) of the modulated signal, the signal processing needed and the capacity of the base band equipment is reduced. Finally, receiving diversity is also possible since the orientation of the Rydberg sensor(s) can adjusted to correspond to the polarization of the arriving electromagnetic field. Thus, disturbance of the desired RF signal is kept to a minimum, allowing the detection of even lower power density electromagnetic fields.

In a first aspect of the present invention, computer-readable media is provided, the computer-readable media having computer-executable instructions embodied thereon that, when executed, perform a method of utilizing a Rydberg sensor in a passive antenna radio system. The method comprises receiving an indication a passive antenna comprising one or more transmitting elements and a Rydberg sensor is communicatively coupled to a remote radio unit (RRU), wherein the Rydberg sensor replaces one or more receiving elements in the passive antenna. The method also comprises receiving radio frequency (RF) carrier signals at the Rydberg sensor. The method further comprises providing a modulated signal corresponding to the RF carrier signals from the Rydberg sensor to the RRU via an optical fiber.

A second aspect of the present disclosure is directed to a method of utilizing a Rydberg sensor in a passive antenna radio system. The method comprises replacing receiver portions of a passive antenna with a Rydberg sensor. The method also comprises receiving radio frequency (RF) carrier signals at the Rydberg sensor. The method further comprises providing a modulated signal corresponding to the RF carrier signals from the Rydberg sensor to the base station via an optical fiber.

Another aspect of the present disclosure is directed to a Rydberg sensor passive antenna array system. The system comprises a passive antenna comprising one or more transmitting elements and one or more Rydberg sensors, the one or more transmitting elements communicatively coupled to a remote radio unit (RRU) via a coaxial cable and the one or more Rydberg sensors communicatively coupled to the RRU via an optical fiber. The system also comprises the RRU comprising one or more power amplifiers, and a radio frequency (RF) control component configured to transmit an outgoing RF signal from a base station via the one or more transmitting elements of the passive antenna, wherein the one or more Rydberg sensors are configured to receive an incoming RF signal.

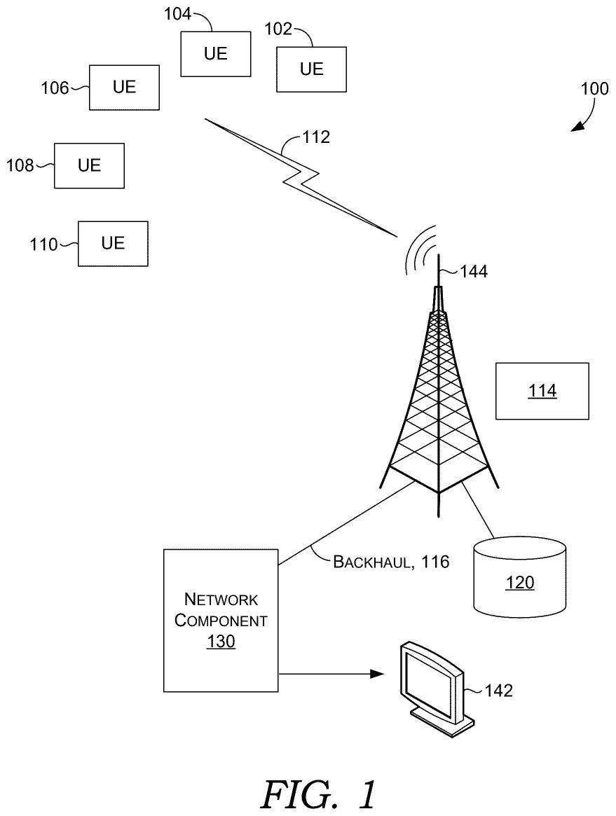

FIG. 1 illustrates an example of a network environment 100 suitable for use in implementing embodiments of the present disclosure. The network environment 100 is but one example of a suitable network environment and is not intended to suggest any limitation as to the scope of use or functionality of the disclosure. Neither should the network environment 100 be interpreted as having any dependency or requirement to any one or combination of components illustrated.

Network environment 100 includes user equipment (UE) devices 102, 104, 106, 108, and 110, base station 114 (which may be a cell site or the like), Rydberg sensor passive antenna radio system 144, and one or more communication channels 112. The communication channels 112 can communicate over frequency bands assigned to the carrier. In network environment 100, UE devices may take on a variety of forms, such as a personal computer (PC), a user device, a smart phone, a smart watch, a laptop computer, a mobile phone, a mobile device, a tablet computer, a wearable computer, a personal digital assistant (PDA), a server, a CD player, an MP3 player, a global positioning system (GPS) device, a video player, a handheld communications device, a workstation, a router, a hotspot, and any combination of these delineated devices, or any other device (such as the computing device (500) that communicates via wireless communications with the base station 114 using Rydberg sensor passive antenna radio system 144 in order to interact with a public or private network.

In some aspects, each of the UEs 102, 104, 106, 108, and 110 may correspond to computing device 500 in FIG. 5. Thus, a UE can include, for example, a display(s), a power source(s) (e.g., a battery), a data store(s), a speaker(s), memory, a buffer(s), a radio(s) and the like. In some implementations, for example, devices such the UEs 102, 104,106, 108, and 110 comprise a wireless or mobile device with which a wireless telecommunication network(s) can be utilized for communication (e.g., voice and/or data communication). In this regard, the user device can be any mobile computing device that communicates by way of a wireless network, for example, a 3G, 4G, 5G, LTE, CDMA, or any other type of network.

In some cases, UEs 102, 104, 106, 108, and 110 in network environment 100 can optionally utilize one or more communication channels 112 to communicate with other computing devices (e.g., a mobile device(s), a server(s), a personal computer(s), etc.) through Rydberg sensor passive antenna system 144 mounted on base station 114. Base station 114 may be a gNodeB in a 5G or 6G network as described herein.

The network environment 100 may be comprised of a telecommunications network(s), or a portion thereof. A telecommunications network might include an array of devices or components (e.g., one or more base stations), some of which are not shown. Those devices or components may form network environments similar to what is shown in FIG. 1, and may also perform methods in accordance with the present disclosure. Components such as terminals, links, and nodes (as well as other components) can provide connectivity in various implementations. Network environment 100 can include multiple networks, as well as being a network of networks, but is shown in more simple form so as to not obscure other aspects of the present disclosure.

The one or more communication channels 112 can be part of a telecommunication network that connects subscribers to their immediate telecommunications service provider (i.e., home network carrier). In some instances, the one or more communication channels 112 can be associated with a telecommunications provider that provides services (e.g., 3G network, 4G network, LTE network, 5G network, and the like) to user devices, such as UEs 102, 104, 106, 108, and 110. For example, the one or more communication channels may provide voice, SMS, and/or data services to UEs 102, 104, 106, 108, and 110, or corresponding users that are registered or subscribed to utilize the services provided by the telecommunications service provider. The one or more communication channels 112 can comprise, for example, a 1x circuit voice, a 3G network (e.g., CDMA, CDMA2000, WCDMA, GSM, UMTS), a 4G network (WiMAX, LTE, HSDPA), or a 5G network or a 6G network.

In some implementations, base station 114 is configured to communicate with a UE, such as UEs 102, 104, 106, 108, and 110, that are located within the geographic area, or cell, covered by radio antennas or antenna arrays of base station 114. The radio antennas of base station 114 may incorporate Rydberg sensor passive antenna system 144 as described below in FIG. 2. Base station 114 may include one or more base stations, base transmitter stations, radios, antennas, antenna arrays, power amplifiers, transmitters/receivers, digital signal processors, control electronics, GPS equipment, and the like. In particular, base station 114 may selectively communicate with the user devices using dynamic beamforming.

As shown, base station 114 is in communication with a network component 130 and at least a network database 120 via a backhaul channel 116. As the UEs 102, 104, 106, 108, and 110 collect data, the data can be automatically communicated by each of the UEs 102, 104, 106, 108, and 110 to the base station 114. Base station 114 may store the data communicated by the UEs 102, 104, 106, 108, and 110 at a network database 120. Alternatively, the base station 114 may automatically retrieve the data from the UEs 102, 104, 106, 108, and 110, and similarly store the data in the network database 120. The data may be communicated or retrieved and stored periodically within a predetermined time interval which may be in seconds, minutes, hours, days, months, years, and the like. With the incoming of new data, the network database 120 may be refreshed with the new data every time, or within a predetermined time threshold so as to keep the status data stored in the network database 120 current. For example, the data may be received at or retrieved by the base station 114 every 10 minutes and the data stored at the network database 120 may be kept current for 30 days, which means that status data that is older than 30 days would be replaced by newer status data at 10 minute intervals. Data collected by the UEs 102, 104, 106, 108, and 110 can include, for example, service state status, the respective UE's current geographic location, a current time, a strength of the wireless signal, available networks, and the like.

The network component 130 is configured to retrieve signal information, UE device information, latency information, signal information, antenna information, and metrics from the base station 114, Rydberg sensor passive antenna radio system 144, or one of the UEs 102, 104, 106, 108, and 110. The network component 130 may determine which antenna or antennas of the Rydberg sensor passive antenna radio system 144 on base station 114 is used by a given UE to communicate. The network component 130 may also determine which antenna or antennas of the Rydberg sensor passive antenna radio system 144 are used by each of UEs 102, 104, 106, 108, and 110 for communication. In some aspects, the network component 130 selects a wavelength of a laser in a Rydberg sensor of the Rydberg sensor passive antenna radio system 144 to correspond to an RF operating frequency. In other aspects, the network component 130 adjusts an orientation of a Rydberg sensor in the Rydberg sensor passive antenna radio system 144 to correspond to a polarization of an arriving EM field.

An example of a Rydberg sensor suitable for use in a Rydberg sensor active antenna radio system comprises a glass cell containing one or more species of vaporized alkaline element atoms. At least one of each atom's electron is excited to a very high energy state and can be used as sensors to detect modulated information on RF carrier signals. By passing a probe laser and a coupling laser through the vapor, a photo detector can be instrumented to read the data. Additionally, the Rydberg may be able to extract the IQ diagram of the modulated signal which may reduce the signal processing needed and the capacity of the base band equipment.

In FIG. 2, a diagram of an exemplary Rydberg sensor passive antenna radio system 200, suitable for use in a network environment, in accordance with aspects herein, is illustrated. As shown, the Rydberg sensor passive antenna array system 200 comprises a passive antenna 210 comprising one or more transmitting elements 212 and one or more Rydberg sensors 214. The one or more transmitting elements 212 are communicatively coupled to a RRU 202 via a coaxial cable and the one or more Rydberg sensors 214 are communicatively coupled to the RRU 202 via an optical fiber. The RRU 202 comprises one or more power amplifiers, and a radio frequency (RF) control component configured to transmit an outgoing RF signal from a base station via the one or more transmitting elements 212 of the passive antenna 210. The one or more Rydberg sensors 214 are configured to receive an incoming RF signal. Also as shown, duplexers/filters for dedicated transmitting and receiving paths are removed from the RRU 202, resulting in a cleaner RF system (i.e., lower noise in uplink).

FIG. 3 is an exemplary passive antenna with a Rydberg sensor, suitable for use in a network environment, in accordance with aspects herein, is illustrated. As shown, the receiving elements of the antenna have been replaced with Rydberg sensors 310. However, both the low band transmitting elements 320 and the high band transmitting elements remain.

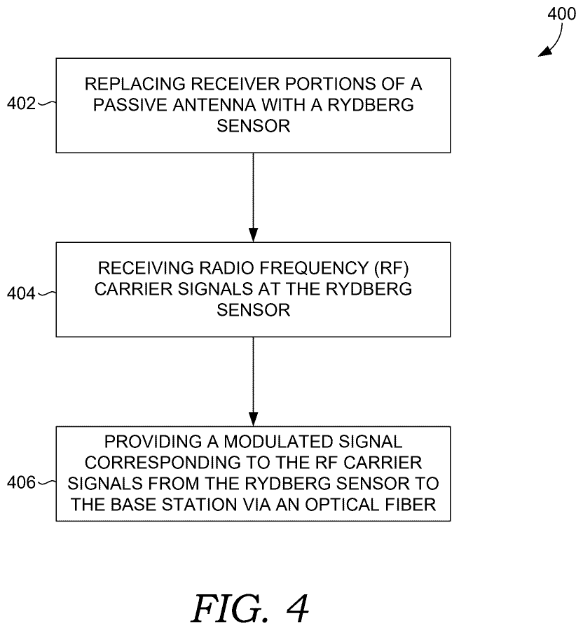

FIG. 4 is a flow diagram of an exemplary method for utilizing a Rydberg sensor in a passive antenna radio system, in accordance with aspects herein. The method 400 begins with replacing, at step 402, receiver portions of a passive antenna with a Rydberg sensor. The one or more Rydberg sensors may comprise a glass cell containing one or more species of vaporized alkaline element atoms. The one or more species of vaporized alkaline element atoms may be utilized as sensors to detect modulated information on RF carrier signals. In aspects, duplexers and filters are removed from the RRU for dedicated transmitter and receiver paths in the active antenna radio system.

The method 400 also comprises receiving, at step 404, receiving RF carrier signals at the Rydberg sensor. In some aspects, a wavelength of a laser in the one or more Rydberg sensors is selected to correspond to an RF operating frequency. In some aspects, a wavelength of a laser in the one or more Rydberg sensors is selected to correspond to an RF operating frequency.

The method 400 further comprises providing, at step 406, a modulated signal corresponding to the RF carrier signals from the Rydberg sensor to a base station via an optical fiber. Additionally or alternatively, an orientation of the one or more Rydberg sensors may be adjusted to correspond to a polarization of an arriving electromagnetic field. In some aspects, the one or more Rydberg sensors extract an in-phase component and a quadrature-phase component (IQ) of the modulated signal. Moreover, in some aspects, the base band capacity at a base station corresponding to the RRU can be reduced.

FIG. 5 depicts an exemplary computing device suitable for use in implementations of the present disclosure, in accordance with aspects herein. With continued reference to FIG. 5, computing device 500 includes bus 502 that directly or indirectly couples the following devices: memory 504, one or more processors 506, one or more presentation components 508, input/output (I/O) ports 512, I/O components 510, radio 516, transmitter 518, and power supply 514. Bus 502 represents what may be one or more busses (such as an address bus, data bus, or combination thereof). Although the devices of FIG. 5 are shown with lines for the sake of clarity, in reality, delineating various components is not so clear, and metaphorically, the lines would more accurately be grey and fuzzy. For example, one may consider a presentation component such as a display device to be one of I/O components 510. Also, processors, such as one or more processors 506, have memory. The present disclosure hereof recognizes that such is the nature of the art, and reiterates that FIG. 5 is merely illustrative of an exemplary computing environment that can be used in connection with one or more implementations of the present disclosure. Distinction is not made between such categories as “workstation,” “server,” “laptop,” “handheld device,” etc., as all are contemplated within the scope of FIG. 5 and refer to “computer” or “computing device.”

The implementations of the present disclosure may be described in the general context of computer code or machine-useable instructions, including computer-executable instructions such as program components, being executed by a computer or other machine, such as a personal data assistant or other handheld device. Generally, program components, including routines, programs, objects, components, data structures, and the like, refer to code that performs particular tasks or implements particular abstract data types. Implementations of the present disclosure may be practiced in a variety of system configurations, including handheld devices, consumer electronics, general-purpose computers, specialty computing devices, etc. Implementations of the present disclosure may also be practiced in distributed computing environments where tasks are performed by remote-processing devices that are linked through a communications network.

Computing device 500 typically includes a variety of computer-readable media. Computer-readable media can be any available media that can be accessed by computing device 500 and includes both volatile and nonvolatile media, removable and non-removable media. By way of example, and not limitation, computer-readable media may comprise computer storage media and communication media. Computer storage media includes both volatile and nonvolatile, removable and non-removable media implemented in any method or technology for storage of information such as computer-readable instructions, data structures, program modules or other data. Computer storage media includes RAM, ROM, EEPROM, flash memory or other memory technology, CD-ROM, digital versatile disks (DVD) or other optical disk storage, magnetic cassettes, magnetic tape, magnetic disk storage or other magnetic storage devices. Computer storage media does not comprise a propagated data signal.

Communication media typically embodies computer-readable instructions, data structures, program modules or other data in a modulated data signal such as a carrier wave or other transport mechanism and includes any information delivery media. The term “modulated data signal” means a signal that has one or more of its characteristics set or changed in such a manner as to encode information in the signal. By way of example, and not limitation, communication media includes wired media such as a wired network or direct-wired connection, and wireless media such as acoustic, RF, infrared and other wireless media. Combinations of any of the above should also be included within the scope of computer-readable media.

Memory 504 includes computer-storage media in the form of volatile and/or nonvolatile memory. Memory 504 may be removable, nonremovable, or a combination thereof. Exemplary memory includes solid-state memory, hard drives, optical-disc drives, etc. Computing device 500 includes one or more processors 506 that read data from various entities such as bus 502, memory 504 or I/O components 510. One or more presentation components 508 present data indications to a person or other device. Exemplary one or more presentation components 508 include a display device, speaker, printing component, vibrating component, etc. I/O ports 512 allow computing device 500 to be logically coupled to other devices including I/O components 510, some of which may be built into computing device 500. Illustrative I/O components 510 include a microphone, joystick, game pad, satellite dish, scanner, printer, wireless device, etc.

The radio 516 represents one or more radios that facilitate communication with a wireless telecommunications network. While a single radio 516 is shown in FIG. 5, it is contemplated that there may be more than one radio 516 coupled to the bus 502. In aspects, the radio 516 utilizes a transmitter 518 to communicate with the wireless telecommunications network. It is expressly conceived that a computing device with more than one radio 516 could facilitate communication with the wireless telecommunications network via both the first transmitter 518 and an additional transmitters (e.g. a second transmitter). Illustrative wireless telecommunications technologies include CDMA, GPRS, TDMA, GSM, and the like. The radio 516 may additionally or alternatively facilitate other types of wireless communications including Wi-Fi, WiMAX, LTE, 3G, 4G, LTE, 5G, NR, VoLTE, or other VoIP communications. As can be appreciated, in various embodiments, radio 516 can be configured to support multiple technologies and/or multiple radios can be utilized to support multiple technologies. A wireless telecommunications network might include an array of devices, which are not shown so as to not obscure more relevant aspects of the invention. Components such as a base station, a communications tower, or even base stations (as well as other components) can provide wireless connectivity in some embodiments.

Many different arrangements of the various components depicted, as well as components not shown, are possible without departing from the scope of the claims below. Embodiments of our technology have been described with the intent to be illustrative rather than restrictive. Alternative embodiments will become apparent to readers of this disclosure after and because of reading it. Alternative means of implementing the aforementioned can be completed without departing from the scope of the claims below. Certain features and subcombinations are of utility and may be employed without reference to other features and subcombinations and are contemplated within the scope of the claims.

The invention claimed is:

1. One or more computer-readable media having computer-executable instructions embodied thereon that, when executed, perform a method of utilizing a Rydberg sensor in a passive antenna radio system, the method comprising:
receiving an indication a passive antenna comprising one or more transmitting elements and a Rydberg sensor is communicatively coupled to a remote radio unit (RRU), wherein the Rydberg sensor replaces one or more receiving elements in the passive antenna;
receiving radio frequency (RF) carrier signals at the Rydberg sensor; and
providing a modulated signal corresponding to the RF carrier signals from the Rydberg sensor to the RRU via an optical fiber.

2. The media of claim 1, further comprising reducing base band capacity at a base station corresponding to the RRU.

3. The media of claim 1, further comprising removing duplexers and filters for dedicated transmitter and receiver paths in the passive antenna radio system.

4. The media of claim 1, further comprising adjusting an orientation of the Rydberg sensor to correspond to a polarization of an arriving electromagnetic (EM) field.

5. The media of claim 1, further comprising extracting, by the Rydberg sensor, an in-phase component and a quadrature-phase component (IQ) of the modulated signal.

6. The media of claim 1, further comprising selecting a wavelength of a laser in the Rydberg sensor to correspond to an RF operating frequency.

7. A method of utilizing a Rydberg sensor in a passive antenna radio system, the method comprising:
replacing receiver portions of a passive antenna with a Rydberg sensor;
receiving radio frequency (RF) carrier signals at the Rydberg sensor; and
providing a modulated signal corresponding to the RF carrier signals from the Rydberg sensor to the base station via an optical fiber.

8. The method of claim 7, further comprising reducing base band capacity at the base station.

9. The method of claim 7, further comprising removing duplexers and filters for dedicated transmitter and receiver paths in the passive antenna radio system.

10. The method of claim 7, further comprising adjusting an orientation of the Rydberg sensor to correspond to a polarization of an arriving electromagnetic (EM) field.

11. The method of claim 7, further comprising extracting, by the Rydberg sensor, an in-phase component and a quadrature-phase component (IQ) of the modulated signal.

12. The method of claim 7, further comprising selecting a wavelength of a laser in the Rydberg sensor to correspond to an RF operating frequency.

13. A Rydberg sensor passive antenna array system, comprising:
a passive antenna comprising one or more transmitting elements and one or more Rydberg sensors, the one or more transmitting elements communicatively coupled to a remote radio unit (RRU) via a coaxial cable and the one or more Rydberg sensors communicatively coupled to the RRU via an optical fiber; and
the RRU comprising one or more power amplifiers, and a radio frequency (RF) control component configured to transmit an outgoing RF signal from a base station via the one or more transmitting elements of the passive antenna, wherein the one or more Rydberg sensors are configured to receive an incoming RF signal.

14. The Rydberg sensor passive antenna array system of claim 11, further comprising an antenna power supply configured to provide power to the one or more Rydberg sensors.

15. The Rydberg sensor passive antenna array system of claim 11, wherein duplexers and filters are removed for dedicated transmitter and receiver paths in the RRU.

16. The Rydberg sensor passive antenna array system of claim 11, wherein a wavelength of a laser in the one or more Rydberg sensors is selected to correspond to an RF operating frequency.

17. The Rydberg sensor passive antenna array system of claim 13, wherein the one or more Rydberg sensors comprise a glass cell containing one or more species of vaporized alkaline element atoms.

18. The Rydberg sensor passive antenna array system of claim 13, wherein one or more species of vaporized alkaline element atoms are utilized as sensors to detect modulated information on RF carrier signals.

19. The Rydberg sensor passive antenna array system of claim 13, wherein the one or more Rydberg sensors comprise a probe laser, a coupling laser, and a photo-detector.

20. The Rydberg sensor passive antenna array system of claim 19, wherein the photo-detector is configured to read data from an RF carrier signal when the probe laser and the coupling laser are passed through the one or more species of vaporized alkaline element atoms in the glass cell.
